(19) United States
(12) Patent Application Publication
(10) Pub. No.: US 2011/0034338 A1
(43) Pub. Date: Feb. 10, 2011

(54) CRITICAL CURRENT DENSITY ENHANCEMENT VIA INCORPORATION OF NANOSCALE Ba2(Y,RE)TaO6 IN REBCO FILMS

(76) Inventors: Amit Goyal, Knoxville, TN (US); Claudia Cantoni, Knoxville, TN (US); Eliot Specht, Knoxville, TN (US); Sung-Hun Wee, Knoxville, TN (US)

Correspondence Address: NOVAK DRUCE +QUIGG LLP/UTB, CITY PLACE TOWER, 525 OKEECHOBEE BLVD., 15TH FLR, WEST PALM BEACH, FL, 33401, US

(21) Appl. No.: 12/850,521

(22) Filed: Aug. 4, 2010

Related U.S. Application Data
(60) Provisional application No. 61/231,176, filed on Aug. 4, 2009.

(51) Int. Cl. H01L 39/00; H01L 39/24; B32B 9/00; B05D 5/12; C23C 14/34

(52) U.S. Cl. 505/150; 505/470; 505/473; 505/475; 428/330; 428/114; 427/62; 204/192.24; 977/773; 977/762

(57) ABSTRACT

A superconducting article includes a substrate having a biaxially textured surface, and an epitaxial biaxially textured superconducting film supported by the substrate. The epitaxial superconducting film includes particles of Ba₂RETaO₆ and is characterized by a critical current density higher than 1 MA/cm² at 77K, self-field. In one embodiment the particles are assembled into columns. The particles and nanocolumns of Ba₂RETaO₆ defects enhance flux pinning which results in improved critical current densities of the superconducting films. Methods of making superconducting films with Ba₂RETaO₆ defects are also disclosed.

### CROSS-REFERENCE TO RELATED APPLICATIONS

This Application claims priority to U.S. Provisional Patent Application No. 61/231,176, entitled “Critical Current Density Enhancement via Incorporation of Nanoscale Ba₂(Y,RE)TaO₆ in REBCO Films,” filed Aug. 4, 2009, the entirety of which is incorporated herein by reference.

### STATEMENT REGARDING FEDERALLY SPONSORED RESEARCH OR DEVELOPMENT

The United States Government has rights in this invention pursuant to Contract No. DE-AC05-00OR22725 between the United States Department of Energy and UT-Battelle, LLC.

### FIELD OF THE INVENTION

This invention relates to superconducting materials and more particularly to the pinning enhancement of superconducting materials.

### BACKGROUND OF THE INVENTION

Methods for the preparation of films of high temperature superconductor (HTS) materials on various substrates are well known. These methods have been instrumental for converting HTS materials into tapes and wires, a necessary step in the effort for integrating these materials as wiring into conventional electrical grid systems and devices. Several companies produce HTS wires and tapes of various lengths.

The first HTS tapes suffered from unacceptably low critical current densities, a problem caused by poor alignment of grains in the FITS film or coating with grains of the substrate. Several techniques have therefore been developed to fabricate wires or tapes wherein grain alignment is produced. Of particular note is epitaxial growth of superconductors on such ordered substrates as the Rolling-Assisted-Biaxially-Textured-Substrates (RABiTS). RABiTS substrates typically include a textured metal underlayer (for example, nickel or nickel alloy) and an epitaxial buffer layer (for example, Y₂O₃ and/or yttria-stabilized zirconia, YSZ, and/or cerium oxide, CeO₂). Epitaxial superconductors on biaxially-textured substrates have significantly improved critical current densities of HIS tapes, and thus, improved suitability for commercial applications.

A problem of FITS tapes and wires is the dissipation in critical current density (typically expressed as J_{c}) of the superconductor film when the superconductor film is exposed to an external magnetic field. Since external magnetic fields (typically as high as 5 Tesla, or higher) are prevalent in most commercial and industrial applications, there has been a significant effort to incorporate design features into the superconductor film that mitigate these current density losses. One particularly promising method has been to introduce structural defects (i.e., pinning defects) into the superconductor film. The pinning defects have been found to significantly reduce current density losses in superconductor films in the presence of an external magnetic field.

Flux pinning is the phenomenon that magnetic flux lines do not move (or are “pinned”) in spite of the Lorentz force acting on them inside a current-carrying Type H superconductor. Flux pinning is desirable in high-temperature ceramic superconductors to prevent “flux creep”, which can create a pseudo-resistance and depress both critical current density and critical field. Degradation of a high-temperature superconductor's properties due to flux creep is a limiting factor in the use of these superconductors. In order to realize the full potential of high temperature superconducting wires (HTS coated conductors) for various commercial electric-power equipment, the flux pinning properties of REBa₂Cu₃O₇ films (REBCO, RE=Y or a rare earth element) need to be improved in a controlled, reproducible and practical fashion. Improvements in pinning efficiency not only enhance the critical current density (J_{c}) under high magnetic fields (B), but also may help reduce the field dependent anisotropy in J_{c} for in-field orientations ranging from the ab-plane to the c-axis. The latter advancement is especially important for such power utility applications as motors, generators, and transmission lines, where HTS cables experience varying magnetic field strengths and directions.

Flux pinning is only possible when there are defects in the crystalline structure of the superconductor (usually resulting from grain boundaries or impurities). Physical methods such as laser scribing or photolithographic patterning have been utilized to introduce pinning defects into the superconductor film. Recent research has also been conducted on introducing such defects into superconducting films by growing superconducting films epitaxially on substrates possessing microstructural defects.

In recent years, the issue of improving the effective pinning of magnetic flux lines in HTS films has been successfully addressed by many groups through manipulation of defects in REBCO film matrix. That is, through various methods additional pinning centers of different sizes and morphologies, in addition to the existing naturally formed growth-induced defects, have been introduced into REBCO films. One particularly successful and heavily studied dopant is BaZrO₃ (BZO), first incorporated into the YBCO films, in the form of 5-100 nm size particles, by pulsed laser deposition (PLD). This was followed by the demonstration of strain-induced formation of columnar defects, comprising self-assembled nanodots and/or nanorods of BZO within the superconducting matrix. Similar columnar defects were also observed by incorporation of yttria-stabilized zirconia (YSZ) in REBCO films. Similar columnar defects were also observed by incorporation of yttria-stabilized zirconia (YSZ) in REBCO films. Enhanced flux pinning through Zr additions by MOCVD has been described in Enhanced flux pinning by BaZrO3 and (Gd, Y)2O3 nano-structures in metal organic chemical vapor deposited GdYBCO high temperature superconductor tapes,” Y. Chen, V. Selvamanickam, Y. Zhang, Y. L. Zuev, C. Cantoni, E. D. Specht, M. P. Parantharnan, T. Aytug, A. Goyal and D. Lee, App!. Phys. Lett., vol. 94, Article Number: 062513, 2009 and enhanced flux pinning through Zr additions by MOCVD has also been described in Enhanced flux pinning in MOCVD-YBCO films through Zr additions: systematic feasibility studies; Aytug et al, Supercond. Sci. Technol. 23(2010) 014005. The use of MOCVD to deposit YBCO films is described in Deposition studies and coordinated characterization of MOCVD YBCO films on IBAD-MgO templates; Aytug et al., Supercond. Sci. Technol. 22 (2009) 015008. Incorporation of nanodots and nanorods into superconducting articles and other devices is also described in Patent Application Publications Goyal U.S. 2008/0176749 (Jul. 24, 2008) and Goyal et al U.S. 2009/0088325 (Apr. 2, 2009). The disclosure of these references is hereby incorporated fully by reference. The columnar defects have proven to be very effective for enhancing the pinning performance, especially for fields applied near the c-axis of the REBCO film.

### SUMMARY OF THE INVENTION

An article comprising a substrate having a biaxially textured surface, and an epitaxial biaxially textured superconducting film supported by the substrate is disclosed. The epitaxial superconducting film comprises nanoparticles of double perovskite, Ba₂RETaO₆ and is characterized by a critical current density higher than 1 MA/cm² at 77K, self-field.

The substrate can be selected from the group comprising a single-crystal substrate, a RABiTS substrate, and an IBAD substrate. The particles of Ba₂RETaO₆ can be in the form of aligned columns, aligned within 20 degrees from the c-axis of the superconducting film. The columns can be comprised of particles. The columns can also be comprised of nanorods. The superconducting film can be characterized by an greater than 300 Å/cm at 65K, 3 T.

A method of making a superconducting article comprising a biaxially textured superconducting material and characterized by a critical current density higher than 1 MA/cm² at 77K, self-field, can include the steps of (a) providing a buffered biaxially textured or single crystal substrate and (b) performing simultaneous deposition of the biaxially textured superconducting material and nanoparticles of double perovskite Ba₂RETaO₆.

The deposition step can include an in-situ deposition process selected from the group consisting of pulsed laser ablation, chemical vapor deposition (CVD), metallorganic chemical vapor deposition (MOCVD), sputtering and e-beam co-evaporation. The deposition step can include an ex-situ deposition process selected from the group consisting of chemical solution processes, and an ex-situ BaF₂ process, followed by a heat treatment. The chemical solution process can be selected from the group consisting of TFA-MOD, non-fluorine MOD processes, and reduced fluorine MOD processes.

A method of making a superconducting film comprising a biaxially textured superconducting materialand characterized by a critical current density higher than 1 MA/cm² at 77K, self-field, can include the steps of (a) providing a buffered biaxially textured or single crystal substrate (b) heating the substrate to a preselected deposition temperature under a preselected gas atmosphere and pressure (c) performing simultaneous deposition of the biaxially textured superconducting material and nanoparticles of double perovskite Ba₂RETaO₆.

The simultaneous deposition can be done using an in-situ deposition process selected from the group consisting of pulsed laser ablation, chemical vapor deposition (CVD), metallorganic chemical vapor deposition (MOCVD), sputtering and e-beam co-evaporation. The simultaneous deposition can be done using an ex-situ deposition process selected from the group consisting of chemical solution processes, and an ex-situ BaF₂ process, followed by a heat treatment. The chemical solution process can be selected from the group consisting of TFA-MOD, non-fluorine MOD processes, and reduced fluorine MOD processes.

A superconducting article can comprise a biaxially textured superconducting composition containing RE, Ba, Cu and O and nanoparticles of double perovskite, Ba₂(Y,RE)TaO₆ and being characterized by a critical current density higher than 1 MA/cm² at 77K, self-field. The superconducting composition can comprise REBCO.

The particles of Ba₂RETaO₆ can be in the form of aligned columns, aligned within 20 degrees from the c-axis of the superconducting film. The columns can be comprised of particles. The columns can be comprised of nanorods. The superconducting film can be characterized by an I_{c} greater than 300 Å/cm at 65K, 3 T.

### BRIEF DESCRIPTION OF THE DRAWINGS

A fuller understanding of the present invention and the features and benefits thereof will be obtained upon review of the following detailed description together with the accompanying drawings, in which:

FIG. 1 shows the crystal structure of the double perovskite tantalate phase—Ba₂RETaO₆. On the right shows a plot of lattice mismatches of these compounds as well as some other phases such as RE₂O₃, RE₃TaO₇ with YBCO phase. The plot shows that the lattice mismatch of the double perovskite phase, Ba₂RETaO₆, is higher than that of BZO, i.e. in the range of 8-12%, which is ideal to create enough strain as a result of lattice mismatch and hence vertical self-assembly of columnar defects comprising aligned vertical nanodots or nanorods comprised of Ba₂RETaO₆ (In case RE is the same element in REBCO matrix) or Ba₂(RE₁,RE₂)TaO₆ (In case RE₁ in Ba₂RETaO₆ is different from RE₂ in REBCO matrix and RE₂ includes Y).

FIG. 2 shows X-ray diffraction results from previous work showing the inertness of the phase—Ba₂RETaO₆ with YBCO phase.

FIG. 3 shows X-ray diffraction results for YBCO films with Ba₂RETaO₆ addition. FIG. 3(A) shows θ-2θ scans for YBCO films with and without 4 vol % Ba₂RETaO₆ addition with RE of Yb, Er, and Gd. FIG. 3(B) shows in-plane and out-of plane textures of (Y,Gd)BCO and Ba₂(Y,Gd)TaO₆ phases taken from 4 vol% Ba₂GdTaO₆ doped YBCO film.

FIG. 4 shows transmission electron micrographs of 0.8 μm thick YBCO film with 4 vol % Ba₂GdTaO₆ addition on. IBAD-MgO templates. FIG. 4(A) shows a cross-sectional TEM image showing the presence of splayed columnar defects comprised of self-assembled Ba₂(Y,Gd)TaO₆ nanodots in general along the c-axis. Inset of the figure is a higher magnification image showing a Ba₂(Y,Gd)TaO₆ column. FIG. 4(B) shows a plan-view TEM image showing distribution of high density of Ba₂(Y,Gd)TaO₆ nanocolumns with an average diameter of 6-7 nm and a distance of 15-20 nm separation from each other. Inset of the figure is a higher magnification image showing a Ba₂(Y,Gd)TaO₆ nanoparticle. FIG. 4(C) shows selected area diffraction (SAD) patterns taken from a cross-section TEM specimen indicating the presence of cubic, double perovskite Ba₂(Y,Gd)TaO₆ nanocolumns.

FIG. 5 shows the field dependent J_{c} at 77 K and 65 K for H∥c with the magnetic field up to 8 T (A) and the angular dependent J_{c} at 77 K, 1 T and 65 K, 3 T (B) for YBCO and YBCO+4 vol % Ba₂GdTaO₆ films. All samples have identical film thickness which is 0.8 μm

### DETAILED DESCRIPTION OF THE INVENTION

The present invention incorporates a Ba₂RETaO₆ phase into particles or substantially aligned columns within a superconducting film. Since the Ba₂RETaO₆ phase has a large lattice mismatch with superconducting films, such as REBCO or YBCO films, significant strain is generated by the presence of this phase. Self-aligned or randomly distributed particles of Ba₂RETaO₆ can cause significant improvements in flux pinning, which can result in significant enhancement in the critical current density (J_{c}) of the superconducting film. Also, the strain caused by the lattice mismatch can cause vertical self-assembly of particles of Ba₂(Y, RE)TaO₆ into columns. The particles can also merge to form nanorods. The columns also cause significant improvements in flux pinning, with resulting improvements in J_{c}.

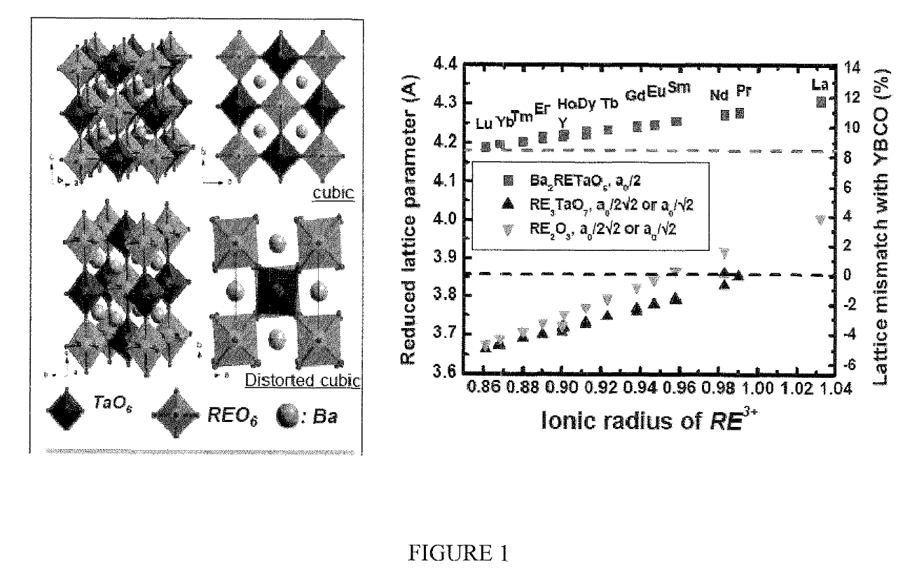

The structure of the Ba₂RETaO₆ phase in the superconducting film is a cubic or distorted cubic double perovskite. FIG. 1 shows the crystal structure of the double perovskite tantalates phase. These compounds have large lattice mismatches with YBCO. FIG. 1B is a plot of the lattice mismatches of these compounds with YBCO, as well as some other phases such as BaZrO₃, RE₂O₃, and RE₃TaO₇. The plot shows that the lattice mismatch of the double perovskite phase, Ba₂RETaO₆, is higher than that of BZO, in the range of 8-12%, which is ideal to create enough strain for the self-assembly of columnar defects comprising aligned particles of Ba₂RETaO₆. Ba₂RETaO₆ accordingly is an excellent candidate for forming self-assembled columnar defects in REBCO films.

The particles and columns of the Ba₂(Y, RE)TaO₆ defects in the superconducting film can be substantially evenly/homogeneously distributed throughout the superconducting film. The concentration of the defects in the superconducting material can vary. In one aspect, the number density of defects can be between 400 and 4×10⁴ μm⁻² corresponding to interspacing distance between particles or columns in the range of 5 to 50 nm in the superconducting film.

The thickness (e.g., width or largest dimension) of the Ba₂(Y, RE)TaO₆ features in the superconducting film is generally of nanoscale dimension, i.e., less than 1 μm thick. For example, in different embodiments, the largest dimension of the features can be less than 500 nm, or less than 200 nm, or less than 100, 90, 80, 70, 60, 50, 40, 30, 20, or less than 10 nm. The smallest dimension of the particle or column features can be greater than 1, 2, 3, 4, 5, 10, 20, 30, 40 or 50 nm. The particles or columns can also have any combination of the aforesaid largest dimensions and smallest dimensions. However, smaller or larger thicknesses of the columnar features are also possible. More typically, the largest dimension of the nanoscale defects is in the range of 1-100 nm. The diameter of the particles will be between 1 nm and 100 nm. The diameter of the particles will depend on the type of processes and processing conditions. In the case of columnar features, the length of the columns will be up to the entire film thickness of REBCO superconducting layer. The length will depend on the type of processes and processing conditions. The width of the columns will be between 1 nm and 100 nm. The width of the columns will depend on the type of processes and processing conditions.

The self-assembled defects are generally disposed linearly, for example, as columns, in the superconducting film in an orientation generally perpendicular to the superconducting film surface (c-axis), or parallel to the direction of film growth. It is also possible that conditions can be employed that could provide for the creation of non-linear (for example, curved or bent) defects in the superconducting film. Furthermore, it is contemplated that conditions can be employed that could provide for linearly or non-linearly propagated defects to depart from a perpendicular orientation to the surface, for example, within +1/−1 degrees to within +90/−90 degrees of the perpendicular, or any angular orientation there between. In one embodiment, the defects are aligned within +20/−20 degrees of the c-axis of the superconducting film.

Superconducting films according to the invention are characterized by a critical current density (J_{c}) higher than 1 MA/cm² at 77K, self-field. Superconducting films according to the invention can also be characterized by an critical current (I_{c}) greater than 300 Å/cm at 65K, 3 T.

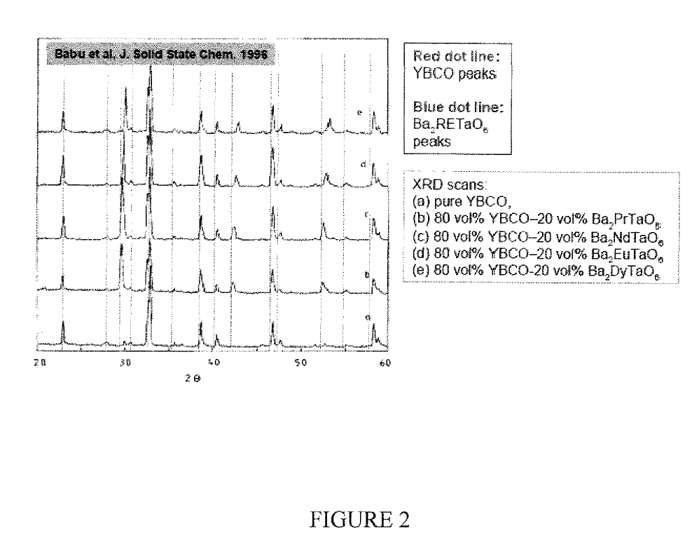

The primary phase of the superconducting film can be one of many high temperature superconductor (HTS) materials known in the art. A high temperature superconducting material is generally characterized by having a superconducting critical temperature (T_{c}) of at least 35 K, and more preferably, greater than 77 K. Currently, a majority of the HTS materials belong to the general class of copper oxide superconducting materials. The HTS material also should be substantially chemically inert with Ba₂(Y, RE)TaO₆. FIG. 2 shows x-ray diffraction results from prior work showing the inertness of the Ba₂(Y, RE)TaO₆ phase with YBCO superconductor [Babu et al, J. Solid State Chem. 1996, incorporated by reference].

In one embodiment, the superconducting film includes a rare-earth (RE) or transition metal barium copper oxide composition (hereinafter, a “metal-barium-copper-oxide” or “REBCO” composition). The rare earth element can be any of the lanthanide or actinide metals listed in the Periodic Table of the Elements (hereinafter, the “Periodic Table”). The lanthanide metals refer predominantly to the elements of the Periodic Table having an atomic number of 57 to 71. The actinide metals generally refer to any of the elements of the Periodic Table having an atomic number of 90 to 103. In a particular embodiment, the metal-barium-copper-oxide material is according to the formula (RE)Ba₂Cu₃O₇, wherein RE is a rare earth or transition metal element. Some examples of suitable RE metals include, yttrium (Y), neodymium (Nd), gadolinium (Gd), thulium (Tm), ytterbium (Yb), lutetium (Lu), and combinations thereof. The transition metals generally refer to any of the elements located in Groups 3-12 of the Periodic Table (i.e., the corresponding scandium through zinc groups). In still another embodiment, the HTS film includes a lanthanum-containing copper oxide material. The lanthanum-containing copper oxide material can include a composition according to the general formula La₂₋ₓMₓCuO₄, wherein x is greater than zero and less than 2, and M is an alkaline earth metal ion, such as Mg, Ca, Sr, or Ba. Some specific examples of such superconducting materials include La_{1.85}Ba_{0.15}CuO₄ (LBCO) and La_{1.85}Sr_{0.15}CuO₄ (LSCO).

Other metal barium copper oxide compositions can also be suitable. For example, in one embodiment, the superconducting material is an yttrium barium copper oxide (YBCO) material. Any of the yttrium barium copper oxide superconducting materials known in the art can be used herein. In one instance, the yttrium barium copper oxide material can be generally described by the formula YBa₂Cu₃O₇₋ₓ, wherein x is generally a number within the approximate range 0≦x≦1. As used herein, the formula YBa₂Cu₃O₇ is ascribed the same meaning, and includes all of the possible different variations, as encompassed by the former broader formula. Some examples of other types of yttrium barium copper oxide materials include Y₃Ba₄Cu₇O₁₆, Y₂Ba₄Cu₇O₁₅, Y₂CaBa₄Cu₇O₁₆/(Y_{0.5}Lu_{0.5})Ba₂Cu₃O₇, (Y_{0.5}Tm_{0.5})Ba₂Cu₃O₇, and (Y_{0.5}Gd_{0.5})Ba₂Cu₃O₇.

In another embodiment, the high temperature superconducting film includes a thallium-containing barium copper oxide composition. More particularly, the composition may be a thallium barium calcium copper oxide material. Any of the thallium barium calcium copper oxide materials can be used herein. In one instance, the thallium barium calcium copper oxide material includes a composition according to the formula TlBa₂Caₙ₋₁CuₙO₂₊₃, wherein n is generally a number greater than 1 and up to 4. In another instance, the thallium barium calcium copper oxide material includes a composition according to any of the formulas Tl₂Ba₂Caₙ₋₁CuₙO₂ₙ₊₂, Tl₂Ba₂Caₙ₋₁CuₙO₂ₙ₊₃, or Tl₂Ba₂Caₙ₋₁CuₙO₂ₙ₊₄, wherein n is generally a number greater than 1 and up to 4. Some specific examples of such superconducting compositions include Tl₂Ba₂Ca₂Cu₃O₁₀ (TBCCO-2223), Tl₂Ba₂CaCu₂O₆, TlBa₂Ca₂Cu₃O₉, and TlBa₂Ca₃Cu₄O₁₁.

In another embodiment, the high temperature superconducting film includes a mercury-containing barium copper oxide material. More particularly, the composition may be a mercury barium calcium copper oxide material. Any of the mercury barium calcium copper oxide materials can be used herein. In a particular embodiment, the mercury barium calcium copper oxide material includes a composition according to the formula HgBa₂Caₙ₋₁CuₙO₂ₙ₊₂, wherein n is a number greater than 1 and up to 4. Some specific examples of such superconducting compositions include HgBa₂Ca₂Cu₃O₈, HgBa₂Ca₂Cu₄O₁₀, HgBa₂(Ca₁₋ₐSrₐ)Cu₃O₈ (wherein 0≦a≦1), and (Hg_{0.8}Tl_{0.2})Ba₂Ca₂Cu₃O₈₊ₓ.

In yet another embodiment, the high temperature superconducting film includes a bismuth- and/or strontium-containing calcium copper oxide material. More particularly, the composition may be a bismuth strontium calcium copper oxide (BSCCO) material. Any of the BSCCO materials can be used herein. In a particular embodiment, the BSCCO material includes a composition according to the formula BiSr₂CaₙCuₙ₊₁O₂ₙ₊₆. Some specific examples of such superconducting compositions include Bi₂Sr₂CaCu₂O₈ (BSCCO-2212) Bi₂Sr₂Ca₂Cu₃O₁₀ (BSCCO-2223), Bi₂Sr₂CaCu₂O₉, and Bi₂Sr₂(Ca_{0.8}Y_{0.2})Cu₂O₈.

Any of the superconducting materials described above can include dopant amounts of other metals that may be included to facilitate certain desired properties of the HTS film. Some examples of rare earth dopants include yttrium (Y), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), or a combination thereof. In a particular embodiment, YBCO film compositions are doped with one or more of the above rare earth metals.

The superconducting film can also be composed of one or more than superconducting layer(s). For example, it may be preferred in certain embodiments to apply a YBCO layer onto a BSCCO layer, or vice-versa.

The superconducting film can be of any suitable thickness. For electrical power applications, the thickness is typically no more than about 5 microns (5 μm) thick, and more typically no more than about 10 μm thick. For example, in different embodiments, the thickness of the superconducting film can be about 5, 4, 3, 2, or 1 μm. However, the thickness is highly dependent on the particular application, and thus, can be of significantly greater thickness (e.g., 10, 15, 20, 25 or more microns), or alternatively, of much lesser thickness (e.g., no more than 1, 0.5, 0.2, or 0.1 microns).

The superconducting films can be formed by many different processes, including in-situ processes and ex-situ processes. In-situ processes include pulsed laser ablation, MOCVD, sputtering or e-beam co-evaporation, chemical vapor deposition (CVD), and metallorganic chemical vapor deposition (MOCVD).

Ex-situ processes include chemical solution processes such as metal organic deposition using trifluoroacetates precursor solution (TFA-MOD), non-fluorine MOD processes, and reduced fluorine MOD processes, and the ex-situ BaF₂ process wherein a precursor film is first deposited, followed by a heat treatment to epitaxially form the film.

The superconducting layer can also be coated with any of a variety of materials that can serve a useful purpose. For example, a non-superconducting metal layer may be applied on the superconducting film to protect the film, such as for corrosion resistance. Alternatively, a coating (e.g., metallic, polymeric, plastic, rubber, paint, or hybrid) can be applied onto the superconducting layer to provide, for example, electrical or magnetic insulation, or a certain level of rigidity or flexibility.

The superconducting film can be supported on or deposited on any of several suitable substrates known in the art. The primary substrate considered herein possesses an ordered (i.e., typically, biaxially-textured) surface upon which the phase-separated layer is deposited. For example, any of the biaxially-textured substrates known in the art can be used as the primary substrate on which the phase-separated layer is deposited. As used herein, “supported on” refers to a layer that is above another layer, while “deposited on” refers to a layer that is above and in physical contact with another layer.

The term “biaxially-textured substrate” as used herein is meant to be synonymous with the related term “sharply biaxially-textured substrate.” By one definition, a biaxially-textured substrate is a polycrystalline substrate wherein the grains are aligned within a specific angular range with respect to one another, as would generally be found on the surface of a bulk single crystal. A polycrystalline material having biaxial texture of sufficient quality for electromagnetic applications can be generally defined as having an x-ray diffraction phi scan peak of no more than 20° full-width-half-maximum (FWHM) and an omega-scan of 10° FWHM. The X-ray phi-scan and omega-scan measure the degree of in-plane and out-of-plane texture, respectively. An example of biaxial texture is the cube texture with orientation {100}<100>, wherein the (100) crystallographic plane of all grains is parallel to the substrate surface and the [100] crystallographic direction is aligned along the substrate length.

Other suitable definitions can also be used for defining a biaxially-textured substrate. For example, a biaxially-textured substrate can be defined as a substrate having a crystallographic orientation such that the substrate possesses a FWHM within 7° , preferably within 5° , and more preferably within 3° throughout the crystal. Furthermore, the biaxially-textured substrate need not be polycrystalline (i.e., multi-grained), but may be single-crystalline (i.e., single-grained).

Several types of biaxially-textured substrates are known, all of which are suitable for the purposes herein. Among them, a class of primary substrates suitable for use herein is the class of rolling assisted, biaxially-textured substrates (RABiTS). The RABiTS method produces a polycrystalline substrate having primarily low angle grain boundaries. Further details of the RABiTS technique and formed substrates can be found in, for example, A. Goyal, et al., J. of Materials Research, vol. 12, pgs. 2924-2940, 1997, and D. Dimos et al., Phys. Rev. B, 41:4038-4049, 1990, the disclosures of which are incorporated herein by reference.

The RABiTS technique provides a simple method for fabricating long lengths of biaxially-textured substrates with primarily low-angle grain boundaries. These substrates have been widely employed for the epitaxial deposition of high temperature superconducting (HTS) materials. A number of U.S. patents directed to the RABiTS process and related process variants have been issued. These include U.S. Pat. Nos. 5,739,086; 5,741,377; 5,846,912; 5,898,020; 5,964,966; 5,958,599; 5,968,877; 6.077,344; 6,106,615; 6,114,287; 6,150,034; 6,156,376; 6,151,610; 6,159,610; 6.180,570; 6,235,402; 6,261,704; 6,270,908; 6,331,199; 6,375,768, 6,399,154; 6,451.450; 6,447,714; 6,440,211; 6,468,591, 6,486,100; 6,599,346; 6,602,313, 6,607,313; 6,607,838; 6,607,839; 6,610,413; 6,610,414; 6,635,097; 6,645,313; 6,537,689, 6,663,976; 6,670,308; 6,675,229; 6.716,795; 6,740,421; 6,764,770; 6,784,139; 6,790,253; 6,797,030; 6,846,344; 6,782,988; 6,890,369; 6,902,600; and 7,087,113, the disclosures of which are incorporated herein by reference in their entireties.

In a preferred embodiment, a RABiTS substrate is prepared generally as follows. Briefly, a deformed metal substrate with a very well-developed copper-type (Cu-type) rolling texture is first provided. The metal can be any suitable metal, and typically a FCC type of metal (e.g., Cu, Co, Mo, Cd, Pd, Pt, Ag, Al, Ni, and their alloys), and more preferably, nickel and its alloys (e.g., NiW). A substrate with a Cu-type rolling texture can be readily identified, as known in the art, and as disclosed in, for example, U.S. Pat. No. 7,087,113. For example, a Cu-type rolling texture generally exhibits the characteristic that the X-ray intensity in the pole figures is concentrated on the β-fiber in Euler space of orientation representation. In other words, a Cu-type rolling texture is generally characterized by an orientation of all the grains in the material lying on the β-fiber. The β-fiber is defined as the tube or fiber running from the B through the S to the C point in Euler space. Cu-type rolling texture is generally best shown using pole figures of (111), (200), and (220) from the substrate or drawing the orientations in Euler Space. Next, the metal with Cu-type rolling texture is annealed at a temperature higher than its secondary recrystallization temperature to provide exaggerated grain growth such that a single grain consumes other grains to form an essentially single crystalline (i.e., single grain) type of material (hereinafter, a “single crystal substrate”).

Typically, at least one buffer layer is epitaxially deposited on the surface of the single crystal substrate. The function of the buffer layer is typically as a chemical barrier between the single crystal substrate and the superconducting layer, thereby preventing reaction between these layers while epitaxially transmitting the ordered crystalline structure of the single crystal substrate to the superconducting layer. Some examples of buffer layers include CeO₂, yttria-stabilized zirconia (YSZ), (RE)₂O₃, wherein RE can be any of the metals already defined above (e.g., Y₂O₃), LaM′O₃, wherein M′ is a transition or main group metal (e.g., LaAlO₃, LaGaO₃, LaMnO₃, LaCrO₃, LaNiO₃), lanthanum zirconate (e.g., La₂Zr₂O₇), SrTiO₃ (and its Nb-doped analog), NdGaO₃, NbTiO₃, MgO, TiN, TiB₂, Pd, Ag, Pt, and Au. Some common RABiTS architectures include, for example, a four-layer architecture, such as CeO₂/YSZ/Y₂O₃/Ni/Ni-W, and a three-layer architecture, such as CeO₂/YSZ/CeO₂/Ni-W.

Another type of biaxially-textured substrate includes the ion-beam-assisted deposition (IBAD) substrate. IBAD processes and resulting substrates are described in, for example, U.S. Pat. Nos. 6,632,539, 6,214,772, 5,650,378, 5,872,080, 5,432,151, 6,361,598,5,872,080, 6,756,139, 6,884,527, 6,899,928, and 6,921,741, the disclosures of which are incorporated herein by reference in their entireties. Typically, an IBAD substrate is characterized by an MgO layer (i.e., “IBAD-MgO”) biaxially grown using ion assist on an Al₂O₃/Y₂O₃-coated polycrystalline nickel-based alloy (generally, Hastelloy) base substrate. The Hastelloy substrate is typically deposited on a polycrystalline copper layer. The Al₂O₃ layer serves primarily as a barrier to prevent upward diffusion of substrate components (i.e., functions as a diffusion barrier layer) while the Y₂O₃ layer serves as a seed layer for the IBAD-MgO nucleation. Often, a homo-epitaxial MgO (i.e., homo-epi MgO) layer is epitaxially grown on the IBAD-MgO layer to improve the texture of the IBAD-MgO layer. A texture-transferring capping layer, typically a perovskite layer, such as LaMnO₃ (LMO), SrRuO₃, or SrTiO₃ (but, more typically, LMO) is deposited on the homo-epi MgO layer, or directly on the IBAD-MgO layer. The texture-transferring layer functions to transfer the texture of the MgO layer to the superconducting layer, i.e., wherein the superconducting layer is generally deposited on the capping perovskite layer. An exemplary and widely used IBAD architecture is Al₂O₃/Y₂O₃/IBAD-MgO/horno-epi MgO/LMO.

Yet another type of biaxially-textured substrate includes the inclined-substrate deposition (ISD) substrate. In the ISD process, the resulting substrate has rotated cube texture and the rotation can be as high as 40-45°. ISD processes and resulting substrates are described in, for example, U.S. Pat. Nos. 6,190,752 and 6,265,353, the disclosures of which are incorporated herein by reference in their entireties. In both the IBAD and ISD processes, a biaxially-textured layer is deposited on a flexible, polycrystalline, untextured substrate.

The flux-pinned superconducting films described herein are particularly applied as improved superconducting tapes or wires. As generally understood in the art, a tape or wire generally refers to an article having a width dimension much smaller than its length dimension. The tape or wire can have a length of, for example, at least 0.1 meters (0.1 m), 0.5 m, 1 m, 5 m, 10 m, 50 m, 100 m, 1 km, or more.

A superconducting tape produced by the method described herein can be used in place of any traditional wiring. In particular embodiments, the superconducting tape is used in, for example, a fault current limiter, power transmission cable, electromagnet coil (i.e., superconducting magnet), motor, turbine, transformer, pump, compressor, communication device (e.g., radiofrequency device), wireless device, engine (e.g., in motor vehicle), power storage device, or electrical generator.

Examples have been set forth below for the purpose of illustration and to describe the best mode of the invention at the present time. However, the scope of this invention is not to be in any way limited by the examples set forth herein: The YBCO films with Ba₂RETaO₆ additions (RE: rare earth elements including Y) were epitaxially grown by pulsed laser deposition (PLD) using a KrF (X=248 nm) excimer laser. The PLD target (2 inch diameter, 0.25 inch thick) was made by mixing YBCO powder and Ba₂RETaO₆ powders using standard ball mixer, followed by densification at 950° C. for 2 h. Ba₂RETaO₆ powders were synthesized by using commercially available powders of RE₂O₃, BaCO₃, and Ta₂O₅ with purities over 99.9% via solid state synthesis process. Laser energy density, repetition rate, and substrate to target distance were 2 J/cm², 10 Hz and 5 cm, respectively. The film growth temperature, Tₛ was 790° C. and the oxygen partial pressure, P(O₂), was 230 mTorr. All depositions were performed on IBAD-MgO templates. The deposition rate of 40 nm/min was obtained during the film growth After deposition, samples were in-situ annealed at Tₛ=500° C. and P(O₂)=500 Torr, and ex-situ annealed at 500° C. for 1 h in flowing O₂ gas after depositing sputtered Ag electrodes onto the films. The standard four-point probe method was used for the transport measurements including superconducting transition temperature, T_{c} and critical current density, J_{c} , with a voltage criterion of 1 μV/cm.

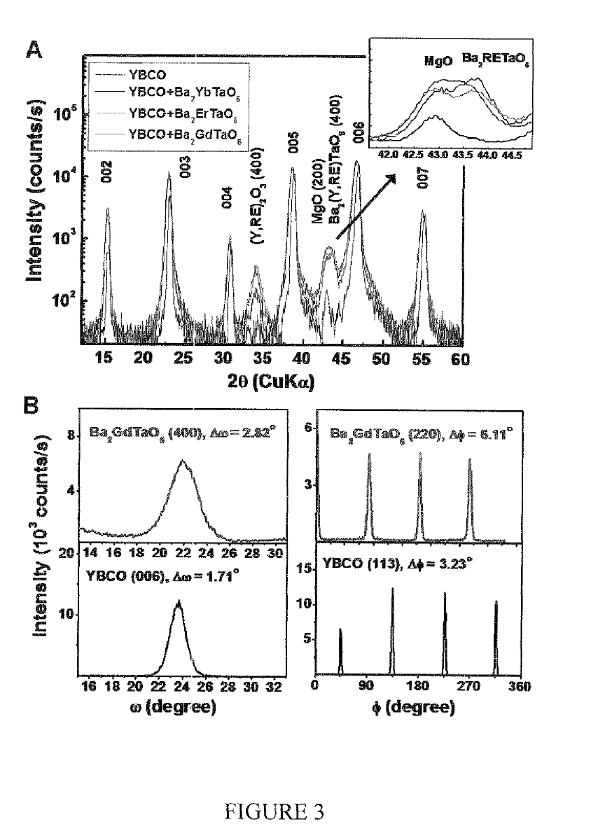

FIG. 3(A) shows θ-2θ x-ray scans for YBCO films with and without 4 vol % BRETO additions with different RE of Yb, Er, and Gd. All films have sharp out-of-plane c-axis orientation with strong (001) peak intensities of YBCO phase. The samples with BRETO additions also have the additional peak at 43˜43.5° corresponding to BRETO(400) which clearly indicates the formation of an oriented BRETO phase within the YBCO film. Since Y³⁺ and RE³⁺ ions have similar ionic radius and same valence, they can be easily substituted with each other and as a result, RE doped YBCO, (Y,RE)BCO, and Y doped BRETO, Ba₂(Y,RE)TaO₆, are actually formed. Based on detailed XRD analysis involving peak broadening, the BRETO(400) peak is determined to come from a nanophase with a particle size ˜6 nm. The inset of the figure shows the narrow scans for Ba₂(Y,RE)Ta0₆ peaks measured at the maximum x-ray power. Even though the MgO(200) peak caused by epitaxial MgO layer consisting of IBAD template slightly overlaps with the Ba₂(Y,RE)TaO₆ peak, both peaks were clearly distinguishable. It is also observed that the Ba₂(Y,RE)TaO₆ peak is shifted to lower angles due to larger lattice parameter with increasing RE³⁺ ionic radius from Yb³⁺ (0.87 Å) to Gd³⁺ (0.94 Å). Strong Ba₂(Y,RE)TaO₆ (220) peaks, which have no overlap with peaks for other phases, were observed in θ-2θ scans taken at rotated x angle of 45°. In addition, small peaks at ˜34° related to (Y,RE)₂O₃ (400) were also detected from the samples with BRETO additions, indicating the presence of small fraction of epitaxial (Y,RE)₂O₃ nanoparticles which have a cubic fluorite structure. These were expected due to the slightly offstoichiometric composition of the YBCO+BRETO targets that were used, i.e., a little excess RE₂O₃ was incorporated in the targets. XRD volume fractions of these (Y,RE)₂O₃ particles were measured to be less than 1%. Due to the small quantity, their effect on flux pinning is expected to be also negligible. FIG. 3(B) reports omega and phi scans for the (Y,Gd)BCO and Ba₂(Y,Gd)TaO₆ phases for the sample with 4 vol % Ba₂GdTaO₆ (BGdTO) addition. Essentially identical omega and phi scans were obtained from films with 4 vol % BRETO with other additions (RE=Yb and Er). The x-ray results indicate that Ba₂(Y,Gd)TaO₆ nanophase grew in cube-on-cube epitaxial relationship with (Y,Gd)BCO matrix with [001]_{BYGdTO}∥[001]_{YGdBCO}. Compared to (Y,Gd)BCO, much larger full-width-half-maximum of omega and phi scans (ΔΩ and Δφ) for Ba₂(Y,Gd)TaO₆ are probably due to some deviation of their alignments with respect to the c axis of YBCO.

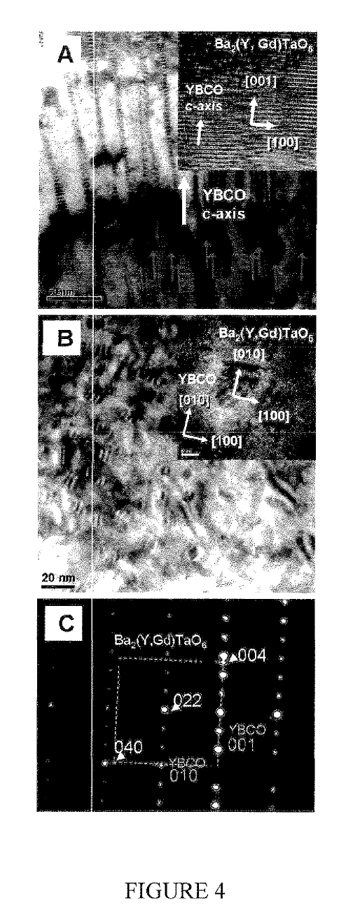

Cross section TEM examination of the 4 vol % BGdTO doped YBCO film confirmed the presence of a nanophase with the morphology of nanocolumns of self-assembled Ba2(Y,Gd)TaO6 nanodots within the (Y,Gd)BCO matrix. As shown in FIG. 4A, the nanocolumns are, in general, aligned to the crystallographic c axis of YBCO but have a splay with some misalignments with respect to the c axis of YBCO. Splayed columnar defects are desirable for flux pinning over larger angular regime as already demonstrated in REBCO films with splayed BZO nanocolumns. The areal density and cross section of Ba2(Y,Gd)TaO6 columns was determined via plan-view TEM examination of the film shown in FIG. 413. The nanodots have an average diameter of 6-7 nm which is consistent with the estimation by XRD and are separated by a distance of 15-20 nm from each other. The matching field, Bφ=φ0/a2, is calculated to be 5-10 T, where φ0=2.07×10-11 T cm2 is the flux quantum and a is the average intercolumn spacing. Selected area diffraction (SAD) pattern in FIG. 4C also shows separate and distinguishable diffraction spots caused by Ba2(Y,Gd)TaO6 cubic, double perovskite structure in addition to those for YBCO.

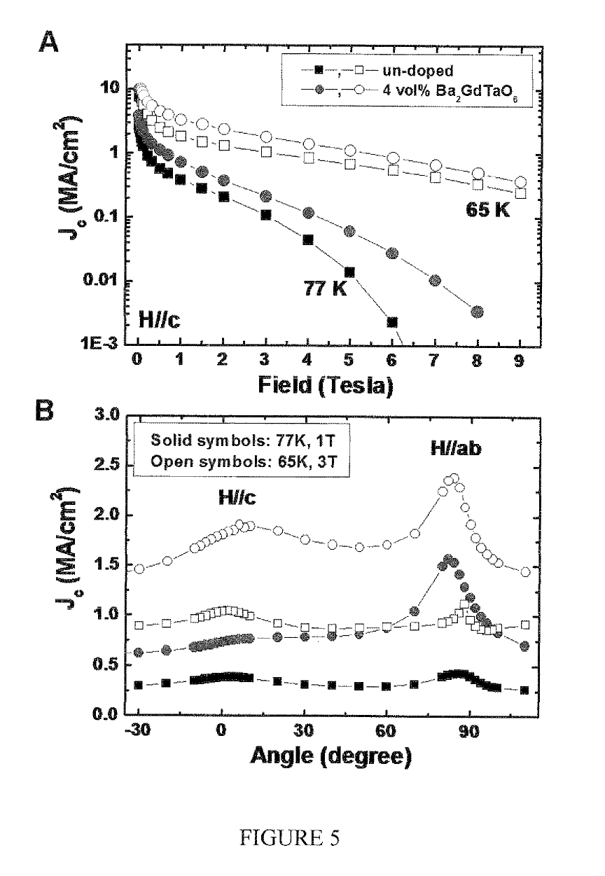

FIG. 5 illustrates the field dependent J_{c} at 77 K, H∥c with the magnetic field up to 8 TFIG. 5 illustrates the field dependent J_{c} at 77 K, H∥c with the magnetic field up to 8 T and the angular dependent J_{c} at 77 K, 1 T (open symbols 65K, 3 T) for un-doped, 4 vol % BGdTO films. Excellent superconducting properties are achieved for YBCO films with such BRETO nanocolumns. These films have no T_{c} reduction over undoped films, implying no poisoning effect due to excellent chemical inertness of BRETO phases with YBCO. The samples with BGdTO addition from 1 up to 4 vol %, have a T_{c} of 87.4-88.3 K. compared to T_{c} of 87.6 K for pure YBCO. This is in contrast to BZO nanocolumn incorporation which reduces T_{c} linearly with BZO vol %. For instance, a 4 vol % BZO nanocolumn incorporated film has a Tc of ˜85 K. Self-field J_{c} is also improved by BGdTO addition. YBCO+4 vol % BGdTO film was measured to have a J_{c} of 3.8 MA/cm², which is much improved than the J_{c} of 2.8 MA/cm² for pure YBCO. In field J_{c} performance over entire field and angular ranges is also improved remarkably by the BGdTO nanocolumns as shown in FIG. 5. Field dependent J_{c} for H∥c in FIG. 5(A) show that BGdTO doped sample has the 1.5-6 fold higher J_{c} from low up to high magnetic fields compared to pure YBCO film, indicating massive enhancement in flux pinning of YBCO film via self-aligned Ba₂(Y,Gd)TaO₆ columns. The irreversibility field, Hᵢᵣᵣ at 77 K is also greatly improved from ˜6.3 T to over 8 T, the highest field at which measurements were made, via BGdTO addition. As shown in FIG. 5(B), angular dependence of J_{c} at 77 K, 1 T and 65 K, 3 T also clearly show twofold to threefold improvement in J_{c} over entire angular range by incorporation of self-assembled Ba₂(Y,Gd)TaO₆ nanocolumns.

### Example 2 (Prophetic)

Superconducting films can be fabricated using chemical solution deposition (CSD) on biaxially textured substrates. The chemical precursor solution is coated onto the substrate at room temperature using slot-die coating and/or dip-coating. The coated substrates are heated in a furnace at a first lower temperature for precursor decomposition and then at a higher temperature in the range of 700-900° C. and preferable in the range of 775-850° C. for formation of REBCO. As formed, the films would be epitaxial on the substrate and phase separated into REBCO+double perovskite B(RE,Y)TO phase with B(RE,Y)TO in the form of nanoparticles. The resulting films can then be cooled and annealed in an oxygen atmosphere to fully oxygenate the REBCO phase. The films are expected to have excellent superconducting properties especially in applied magnetic fields due to the presence of nanoparticles of the B(RE,Y)TO phase. It is preferable that the CSD process is a metallorganie deposition (MOD) process. It is also preferred that at least the Ba in the chemical precursor solution is a fluorine compound.

It should be understood that the examples and embodiments described herein are for illustrative purposes only and that various modifications or changes in light thereof will be suggested to persons skilled in the art and are to be included within the spirit and purview of this application. The invention can take other specific forms without departing from the spirit or essential attributes thereof

We claim:

1. An article comprising a substrate having a biaxially textured surface, and an epitaxial biaxially textured superconducting film supported by said substrate, said epitaxial superconducting film comprising nanoparticles of double perovskite, Ba₂RETaO₆ and being characterized by a critical current density higher than 1 MA/cm² at 77K, self-field.

2. An article in accordance with claim 1, wherein said substrate is selected from the group comprising of a single-crystal substrate, a RABiTS substrate, and an IBAD substrate.

3. An article in accordance with claim 1, wherein said particles of Ba₂RETaO₆ are in the form of aligned columns, aligned within 20 degrees from the c-axis of the superconducting film.

4. An article in accordance with claim 3, wherein said columns are comprised of particles.

5. An article in accordance with claim 3, wherein the columns are comprised of nanorods.

6. An article in accordance with claim 1, wherein said superconducting film is characterized by an Iₑ greater than 300 Å/cm at 65K, 3 T.

7. A method of making a superconducting article comprising a biaxially textured superconducting material and characterized by a critical current density higher than 1 MA/cm² at 77K, self-field, said method comprising the steps of (a) providing a buffered biaxially textured or single crystal substrate and (b) performing simultaneous deposition of the biaxially textured superconducting material and nanoparticles of double perovskite Ba₂RETaO₆.

8. The method of claim 7, wherein said deposition step comprises an in-situ deposition process selected from the group consisting of pulsed laser ablation, chemical vapor deposition (CVD), metal organic chemical vapor deposition (MOCVD), sputtering and e-beam co-evaporation.

9. The method of claim 7, wherein said deposition step comprises an ex-situ deposition process selected from the group consisting of chemical solution processes, and an ex-situ BaF₂ process, followed by a heat treatment.

10. The method of claim 9, wherein the chemical solution process is selected from the group consisting of TFA-MOD, non-fluorine MOD processes, and reduced fluorine MOD processes.

11. A method of making a superconducting film comprising a biaxially textured superconducting materialand characterized by a critical current density higher than 1 MA/cm² at 77K, self-field, said method comprising the steps of:
(a) providing a buffered biaxially textured or single crystal substrate (b) heating the substrate to a preselected deposition temperature under a preselected gas atmosphere and pressure (c) performing simultaneous deposition of the biaxially textured superconducting material and nanoparticles of double perovskite Ba₂RETaO₆.

12. A method in accordance with claim 13 wherein the simultaneous deposition is done using an in-situ deposition process selected from the group consisting of pulsed laser ablation, chemical vapor deposition (CVD), metal organic chemical vapor deposition (MOCVD), sputtering and e-beam co-evaporation.

13. A method in accordance with claim 12 wherein the simultaneous deposition is done using an ex-situ deposition process selected from the group consisting of chemical solution processes, and an ex-situ BaF₂ process, followed by a heat treatment.

14. The method of claim 13, wherein the chemical solution process is selected from the group consisting of TFA-MOD, non-fluorine MOD processes, and reduced fluorine MOD processes.

15. A superconducting article comprising a biaxially textured superconducting composition containing RE, Ba, Cu and O and nanoparticles of double perovskite, Ba₂(Y,RE)TaO₆ and being characterized by a critical current density higher than 1 MA/cm² at 77K, self-field.

16. The superconducting article of claim 15, wherein the superconducting composition comprises REBCO.

17. An article in accordance with claim 15, wherein said particles of Ba₂RETaO₆ are in the form of aligned columns, aligned within 20 degrees from the c-axis of the superconducting film.

18. An article in accordance with claim 15, wherein said columns are comprised of particles.

19. An article in accordance with claim 15, wherein the columns are comprised of nanorods.

20. An article in accordance with claim 15, wherein said superconducting film is characterized by an I_{c} greater than 300 Å/cm at 65K, 3 T.
